(19) United States
(12) Patent Application Publication
(10) Pub. No.: US 2016/0282431 A1
(43) Pub. Date: Sep. 29, 2016

(54) METHOD AND MAGNETIC RESONANCE APPARATUS FOR CORRECTING FIELD DRIFTS OF A HIGHER ORDER THAT OCCUR DUE TO THE OPERATION OF GRADIENT COILS

(71) Applicant: Siemens Aktiengesellschaft, Muenchen (DE)

(72) Inventor: Andrew Dewdney, Neunkirchen am Brand (DE)

(73) Assignee: Siemens Aktiengesellschaft, Muenchen (DE)

(21) Appl. No.: 15/078,231

(22) Filed: Mar. 23, 2016

(30) Foreign Application Priority Data
Mar. 23, 2015 (DE) 102015205150.1

(51) Int. Cl. G01R 33/3873; G01R 33/54; G01R 33/385

(52) U.S. Cl. CPC G01R 33/3873; G01R 33/3852; G01R 33/543

(57) ABSTRACT

In a method and magnetic resonance apparatus for correcting field drifts of a higher order than the zeroth order that occur due to the operation of gradient coils in a magnetic resonance scanner while recording magnetic resonance data, at least one temperature sensor is used to determine the gradient coil temperature directly on the gradient coils, and as a function of the gradient coil temperature, at least one field variable describing at least one part of the field drifts is determined, and the field drifts are corrected by the actuation of the gradient coils and/or shim coils being modified in order to compensate for field drifts described by the field variable, and/or the acquired magnetic resonance data are corrected in post-processing as to the effects of the field drifts described by the field variable.

### BACKGROUND OF THE INVENTION

1. Field of the Invention

The invention concerns a method for correcting field drifts with a higher order than the zeroth order that occur due to the operation of gradient coils in a magnetic resonance scanner while recording magnetic resonance data with the magnetic resonance scanner. The invention also concerns a magnetic resonance apparatus for implementing such a method.

2. Description of the Prior Art

It is known that the use of gradient coils, particularly when utilized in magnetic resonance sequences such as diffusion-weighted imaging, involves a significant increase in the temperature of the gradient coils. This results in field drifts for various reasons. Drifts of the zeroth order of the basic magnetic field, which manifest themselves in shifts of the Larmor frequency, are of first concern. Field drifts of a higher order, in particular linear terms or terms higher than the first order, may also occur. Techniques have been proposed to correct negative effects that occur due to these field drifts, by directly compensating for field drifts, or by post-processing recorded magnetic resonance data.

EP 1 482 320 A2 discloses temperature-stable shimming of a magnetic resonance system using both passive shims and active, resistive shims (shim coils). Based on the fact that the temperature-dependent magnetization of the passive shim elements, and thus the shim effect of the passive shim elements, change, it is proposed in EP 1 482 320 A2 to measure the temperature of the passive shim elements and to adjust the control currents of the active, resistive shim coils in order to maintain the homogeneity of the magnetic field. It has been shown, however, that this method is only able to achieve inadequate improvements, since only an extremely low correlation exists between the field drifts and the temperature of the passive shim elements, for instance shim irons. It is thus generally not possible to make meaningfully valid associations.

DE 10 2012 217 594 A1 discloses a magnetic resonance tomography system having a device for compensating for temperature fluctuations. The basis of this device is to use a temperature sensor that is simple to add, which is provided on a gradient coil connector or on the patient receptacle (the OVC bore), wherein this sensor allows temperature fluctuations in the gradient coil connector or in the OVC bore, which receives the BO coil arrangement to be correlated particularly well with the frequency drifts of the zeroth order (displacements of the Larmor frequency). It is thus proposed in DE 10 2012 217 594 A1 to respond to these shifts of the basic magnetic field (B0 magnetic field) of the zeroth order with an adjustment of the Larmor frequency in the actuation of the gradient coils and/or the radio-frequency coils. In addition and independently of this, the method described by EP 1 482 320 A2 can also be used.

The procedure described by DE 10 2012 217 594 A1 is problematic because although a good correction of field drifts of the zeroth order is enabled, effects of a higher order do not correlate with the temperatures at the measurement locations that are employed, there and consequently cannot be corrected or compensated.

US 2012/0082357 A1 discloses a system and a method for modeling magnetic field drifts induced by the operation of gradient coils. It is proposed therein to determine the suspected field drifts solely on the basis of a theoretical calculation and to use that calculation to correct the recorded magnetic resonance data. Problems with this approach are not only that no measurements take place, but also that not all effects that occur are taken into account. For instance, the effect of cooling systems of the magnetic resonance device is not taken into account in US 2012/0082357 A1, furthermore aside from a pressure variation in the cryostat for the B0 field coils, the gradient operation only results in a “warm bore contribution” which is responsible for the effects of the zeroth order addressed in DE 10 2012 217 594 A1, and in influences on the passive shim elements, as addressed in EP 1 482 320 A2, without a meaningful correlation resulting, which could form the basis of an effective, functioning, measurement-based correction method. Also critical to such a purely calculation-based method is that no precise knowledge of the past gradient activity, the initial state of the system, and the thermal time constants, is available, until the system asymptotically reaches a thermal equilibrium.

The approaches known in the prior art are thus also not able to allow for a complete correction of field drifts of a higher order than the zeroth order, so that in this respect there is a need for improvement. In particular, the hitherto unheeded effects of the physical expansion of the gradient coil, which results in a changed position of the gradient windings and thus in changed sensitivities, should also be addressed by thermally specific displacements of passive shim elements, since an expanding gradient coil physically displaces the passive shim elements from their original position, and thus also involves an additional change in the magnetization change on account of the temperature in the shim iron.

### SUMMARY OF THE INVENTION

An object of the invention thus is to provide a realtime-capable and effective correction method, which is simple to realize, for field drifts of a higher order caused by the operation of gradient coils.

This object is achieved in accordance with the invention by a method for correcting field drifts of a higher order than the zeroth order, which occur due to the operation of gradient coils in a magnetic resonance scanner, while recording magnetic resonance data with the magnetic resonance scanner, wherein at least one temperature sensor is used to determine the gradient coil temperature directly on the gradient coils, and as a function of the gradient coil temperature at least one field variable describing at least one part of the field drifts is determined, and the field drifts are corrected by the actuation of the gradient coils and/or shim coils being modified in order to compensate for field drifts described by the field variable, and/or the acquired magnetic resonance data are corrected by a post-processing procedure (algorithm) that corrects the effects of the field drifts described by the field variable.

The aforementioned modification of the actuation of the gradient coils and/or the shim coils means a modification of the operation thereof from the operation of the gradient coils and/or shim coils that occurs during the course of acquiring magnetic resonance data with the scanner prior to the aforementioned detection of the gradient coil temperature directly on the gradient coils and the determination of the field drifts as a function thereof.

The present invention is based in part on the insight that temperature measured values of the gradient coils themselves, in particular temperature measured by sensors installed in the gradient coil arrangement, correlate extremely well with measured field drifts of a higher order than the zeroth order. It has, moreover, been shown that the effects that result in field drifts of a higher order can be observed independently of the effects that result in field drifts of a zeroth order. Both effects are on different time scales, and it has been shown that the field drifts of a zeroth order, as are discussed for instance in DE 10 2012 217 594 A1, are instead associated with the temperatures on the OVC bore and/or the gradient connector. If terms of the spherical harmonics are observed for instance, mathematical associations can be derived from measured values for the gradient coil temperature and the respective field drift, which are characterized by an extremely high coefficient of determination (R²).

Within the scope of the present invention, it is preferable to determine the field variables, in particular for field drifts described by a term of a spherical harmonics, as a function of an experimentally determined association between the gradient coil temperature and the field variable. This derivability of simple mathematical associations, which indicates the high correlation between the gradient coil temperature and the corresponding field drifts, predestines the present invention for a realtime correction by modified actuation of the gradient coils and/or the shim coils. In particular, series of measurements were recorded as a basis of the invention that indicate that a hysteresis could barely be seen during warm-up and cool-down processes, so that, due to the associations found, currently measured gradient coil temperatures always directly allow for a statement relating to the present field drifts of the order or of the term to which the association applies. For linear drift fields (B11) and drift fields of the second order (precisely A20 and A21), coefficients of determination of greater than 0.988 could be achieved for simple fits with polynomials of the second order. The terms which are actually relevant to the development may depend on the precise embodiment of the magnetic resonance device, so that general combinations of the terms A10, A20, B11, A21, A22, B21 and/or B22 may also be relevant.

It should be noted that the required corrections in the actuation of the gradient coils and/or shim coils naturally inevitably result in a basically known manner only when the field variables are known. If the drift fields to be corrected are described by the field variables and/or field variables even describe a changed sensitivity of the gradient coils, actuation parameters result therefrom for the gradient coils (for the correction of field drifts of the first order) and for the shim coils, which are also typically assigned to specific terms of the spherical harmonics. The precise realtime correction measures therefore do not need to be presented in detail herein, even if an approach is selected in which magnetic resonance data are corrected in a post-processing step. Procedures are known that, on the basis of knowledge about the magnetic resonance fields present during the recording process, allow for a correction of the recorded magnetic resonance data. As mentioned, realtime corrections are preferably to be performed within the scope of the present invention.

As examinations have shown, main effects are those that contribute to the field drifts of a higher order, in particular of the first order and second order, and the previously unconsidered effects of the spatial displacement of windings of the gradient coils and/or of passive shim elements, wherein the former result in a changed sensitivity of the gradient coil. In other words, preferably at least one of the aforementioned field variables relates to field drifts that occur as a result of a change in the sensitivity of the gradient coils, and/or as a result of displacements of passive shim elements of the magnetic resonance scanner that occur due to expansion processes.

Overall, the inventive method allows previously still uncorrectable effects of the operation of the gradient coils to be corrected accurately and simply, in particular in real-time, by virtue of the high correlation of field drifts of a higher order with the gradient coil temperature. An improved quality of the recorded magnetic resonance data is enabled as a result. Only one calibration may be needed in accordance with the invention, which can take place within the scope of a measurement, wherein for instance, as noted, gradient coil temperatures can be measured together with field drifts, particularly in the form of drift fields. A mathematical association between the gradient coil temperatures and the field variables describing the field drifts can then be derived and used within the scope of the present invention in order, less preferably, to perform a correction in the post-processing. In a more efficient and preferred manner the correction is performed during the execution of the magnetic resonance sequence, by adjusting the actuation of the gradient coils, in particular the gradient coil amplitude, and/or the actuation of the shim coils, in particular linear static shim offsets and shim coils of a second order.

In an embodiment, multiple temperature sensors are used, and the gradient coil temperature to be used is determined as an average value of the measured values from at least some of the temperature sensors, but preferably from all temperature sensors. A more precise fluctuation-free measurement results by using multiple temperature sensors, which can be cast into carrier material (a substrate) for the conductor path of the gradient coils for instance.

In a preferred embodiment of the invention, the measured values of the at least one temperature sensor are also evaluated in order to monitor overheating of the gradient coils. Gradient coil arrangements are known that, aside from the gradient coils, also have temperature sensors provided directly on the gradient coils, which emit signals that can be evaluated in order to detect an overheating of the gradient coils, so as to take these coils out of operation once an overheat criterion has been fulfilled (emergency shutdown). Temperature sensors of this type can now be used for a number of purposes, namely within the scope of the known overheat protection measures, as well as within the scope of the inventive correction of field drifts of a higher order, which occur due to the operation of the gradient coils themselves.

With a real-time correction by modifying the actuation of the gradient coils and/or the shim coils, two different, precise realizations are conceivable. It is possible to use a correction installation unit having at least one hardware component, in particular an FPGA that directly evaluates the gradient coil temperature in order to modify control. An extremely quick response to current measured values of the gradient coil temperature is possible in this way, such as by correction currents or generally correction signals being generated, which are supplied to the gradient coils and/or shim coils in addition to the basic operating currents. Alternatively, it is conceivable to use at least one sequence controller, which is configured to generate and emit magnetic resonance sequences in order to record the magnetic resonance data. Then the control currents or control signals for the gradient coils or shim coils to be emitted by the sequencer within the scope of the magnetic resonance sequence in order to record the magnetic resonance data are modified in the sequencer already on the basis of the gradient coil temperature and corresponding calculations. A simpler and more compact design can thus be achieved.

The invention also concerns a magnetic resonance apparatus with a scanner that has a gradient coil arrangement with gradient coils and at least one temperature sensor, and a control computer configured to perform an inventive method. The control computer can have or be connected to, as described above, a correction installation processor and/or a correspondingly modified sequencer. All embodiments relating to the inventive method can apply analogously to the inventive magnetic resonance apparatus, so that the aforementioned advantages thus can also be achieved.

### BRIEF DESCRIPTION OF THE DRAWINGS

FIG. 1 shows the correlation between the gradient coil temperature and various measuring points indicating drift fields.

FIG. 2 is a block diagram of a magnetic resonance apparatus according to a first exemplary embodiment of the present invention.

FIG. 3 is a block diagram of a magnetic resonance apparatus according to a second exemplary embodiment of the present invention.

### DESCRIPTION OF THE PREFERRED EMBODIMENTS

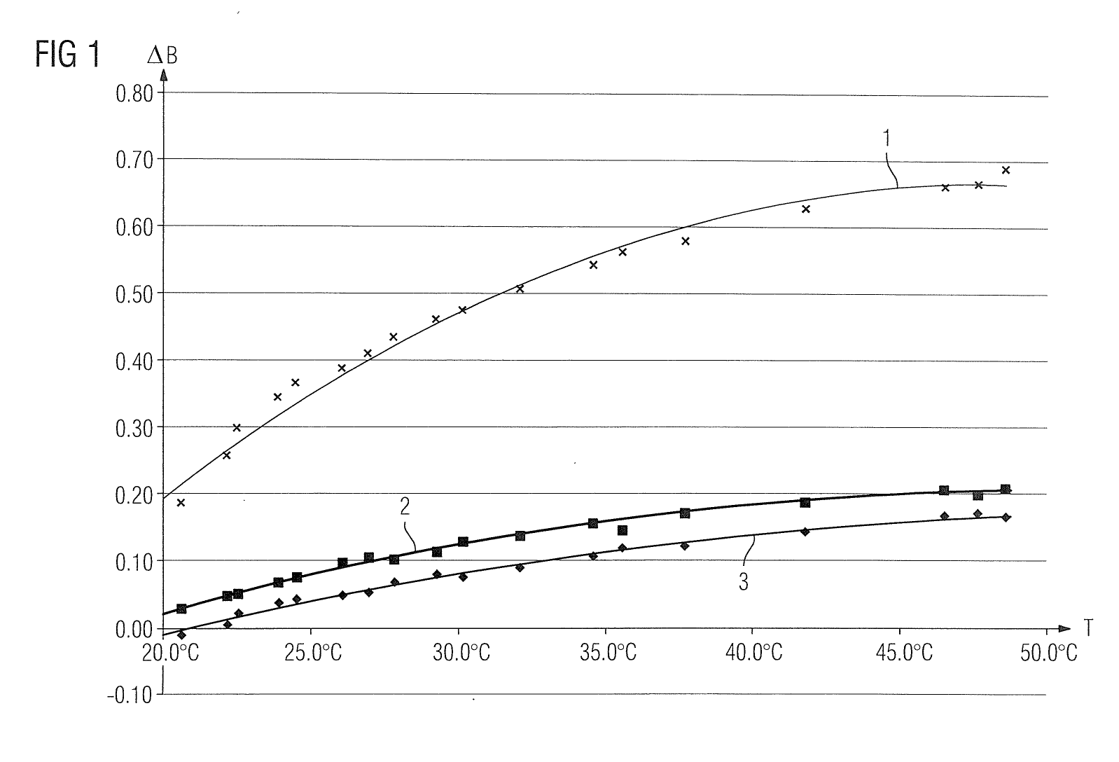

FIG. 1 illustrates the correlation of the gradient coil temperature T with various field drifts, consequently drift fields, of a higher order, which are symbolized by way of the field variable AB plotted on the Y-axis. The measuring points marked by squares designate field drifts of the first order (B 11), the field drifts marked by crosses designate the term A20 of the spherical harmonics and the measuring points marked by diamonds stand for the term A21 of the spherical harmonics. Polynomials of the second order, fitted as curves 1, 2, 3, are also shown. For simple mathematical associations of this type this gives an R² of 0.991 for the B11 terms (curve 2), an R² of 0.9884 for the A20 terms (curve 1) and an R² of 0.9929 for the A21 terms (curve 3). This populates the excellent correlation and the simple mathematical associations, which allow the corresponding field variables to be concluded from the gradient coil temperature, which is measured directly on the gradient coils of the magnetic resonance device.

The associations which were obtained in a calibration measurement as shown by way of example in FIG. 1, can thus be used to determine the field variables describing the field drifts during operation of a magnetic resonance device in the presence of current gradient coil temperatures and to capture correction measures in realtime, preferably by a modified actuation of the gradient coils and the shim coils during the magnetic resonance sequence. It is also conceivable to correct recorded magnetic resonance data in a post-processing step, but this is less preferred.

The field variables described herein as drift fields, in other words field deviations, can finally be directly translated into a modified actuation of the gradient coils and shim coils (A21 coils, A20 coil) assigned to the corresponding terms of the spherical harmonics, particularly since the gradient coils are embodied precisely in order to generate linear overlay fields.

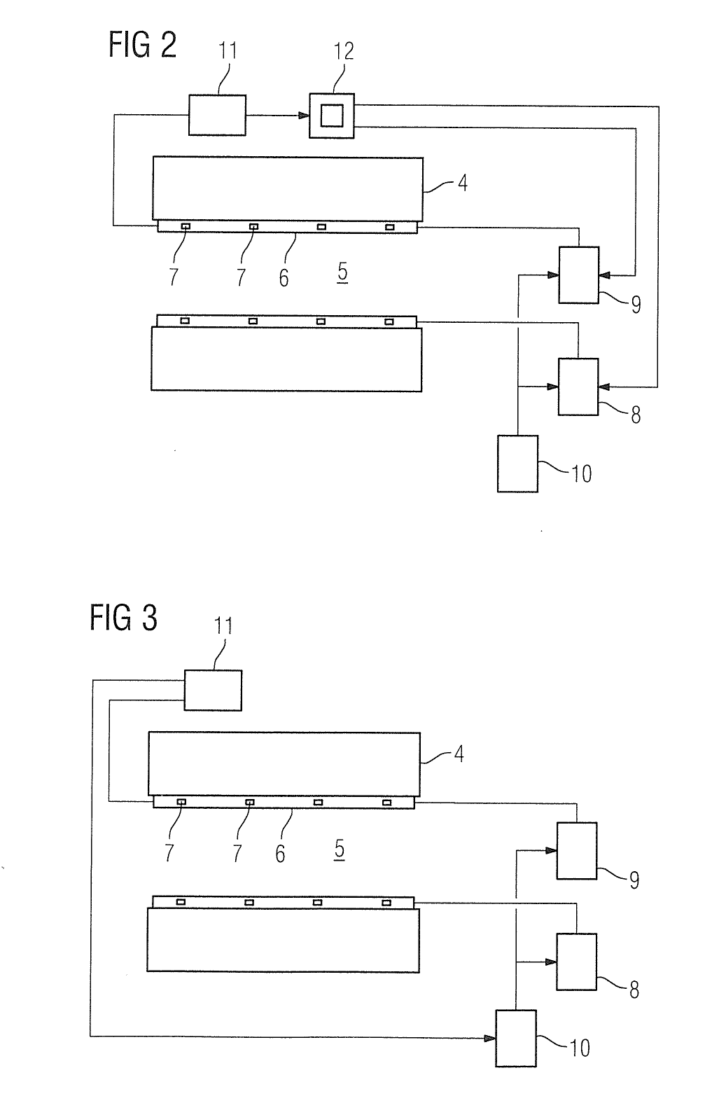

FIGS. 2 and 3 show exemplary embodiments of inventive magnetic resonance apparatuses, in which a realtime correction is performed in various ways by a control computer of the magnetic resonance apparatus. Both block diagrams schematically show the scanner with the basic field magnet unit 4, which contains the super conductive basic magnetic field coils that generate the basic magnetic field (B0 field). The basic field magnet unit 4 defines the patient receptacle 5, which, as is known, is provided so as to surround a gradient coil arrangement 6. Aside from the gradient coils (not shown), shim coils, passive shim elements and temperature sensors 7 are also integrated in the gradient coil arrangement 6. The gradient coils are actuated, as is known, by way of an amplifier 8. A power supply 9 is provided for the shim coils.

A computerized sequence 10 is provided in order to implement the magnetic resonance sequence to acquire magnetic resonance data.

The measured values of the temperature sensors 7 are fed in both embodiments to a temperature monitoring unit 11, which also can be configured to monitor whether an overheating of the gradient coils takes place. If this occurs, an emergency shutoff can be made, for instance.

In the exemplary embodiment according to FIG. 2, a realtime correction installation processor 12 is provided as a further part of the control computer, which can have an FPGA in order to realize control logic that derives correction currents for the actuation of the gradient coils and the shim coils from the gradient coil temperature, and forwards these to the power supply 9 and the amplifier 8.

The gradient coil temperature to be used can be an average value of the measured values of all temperature sensors 7.

In the second exemplary embodiment according to FIG. 3, the gradient coil temperature is forwarded to the sequencer 10, which modifies the actuation processes to be performed within the scope of the magnetic resonance sequence, in order to compensate for field drifts or changes to the gradient coil sensitivity.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for correcting field drifts of a higher order than the zeroth order that occur in a basic magnetic field in a magnetic resonance scanner due to operation of gradient coils in the scanner while acquiring magnetic resonance data with the scanner, said method comprising:
operating a magnetic resonance scanner to acquire magnetic resonance data from a subject therein, including generating a basic magnetic field in the scanner, generating gradient magnetic fields with gradient coils in the scanner being operated with gradient coils operating parameters, and shimming the basic magnetic field with shim coils operated with shim coils data acquisition parameters;
with a temperature sensor, sensing a gradient coil temperature directly on the gradient coils, and emitting a temperature sensor signal representing said temperature;
providing said temperature sensor signal to a computer and, in said computer, executing a field drift determining algorithm to determine a field variable that describes at least a portion of field drifts that occur in said basic magnetic field due to said temperature; and
correcting said field drifts by executing at least one correction algorithm in said computer selected from the group consisting of a gradient coils parameter modification algorithm that modifies said gradient coils data acquisition parameters dependent on said field variable and that results said computer emitting electrical signals to said gradient coils representing modified gradient coils operating parameters, a shim coils parameter modification algorithm that modifies said shim coils data acquisition parameters dependent on said field variable and that results in said computer emitting electrical signals to said shim coils that represent modified shim coils operating parameters, and a post-processing algorithm that corrects, dependent on said field variable, effects of field drifts in said magnetic resonance data acquired from the subject and that results in said computer emitting post-processed magnetic resonance data in electronic form as a data file.

2. A method as claimed in claim 1 comprising, in said computer, determining said field variable as a function of an experimentally determined association between said gradient coil temperature and said field variable.

3. A method as claimed in claim 1 comprising determining said field variable for field effects described by a term of spherical harmonic.

4. A method as claimed in claim 1 comprising, in said computer, determining said field variable as a field variable that describes field drifts that occur as a result of a change insensitivity of said gradient coils, dependent on said temperature.

5. A method as claimed in claim 1 comprising additionally shimming said basic magnetic field with passive shim elements in said scanner and, in said computer, determining said field variable as a field variable that describes physical displacements of said passive shim elements due to expansion resulting from said temperature.

6. A method as claimed in claim 1 comprising providing a plurality of different temperature sensors that each detect a respective temperature value of said temperature directly at said gradient coils, and determining said field variable from an average of at least some of said temperature values.

7. A method as claimed in claim 1 comprising, in said computer, also using said temperature represented by said temperature sensor signal to monitor overheating of said gradient coils.

8. A method as claimed in claim 1 comprising operating said magnetic resonance scanner to acquire said magnetic resonance data from the subject with a computerized sequence controller that operates said gradient coils and said shim coils, and embodying said computer in said computerized sequence controller as a correction installation unit.

9. A method as claimed in claim 8 comprising providing said correction installation unit as a hardware component.

10. A method as claimed in claim 9 comprising providing an FDPA as said hardware component.

11. A magnetic resonance apparatus comprising:
a magnetic resonance data acquisition scanner adapted to receive a subject therein, said scanner comprising a basic field magnet that produces a basic magnetic field in said scanner, and gradient coils and shim coils;
a computerized sequence controller configured to operate said scanner to acquire magnetic resonance data from the subject by operating said gradient coils with gradient coils data acquisition parameters and by operating said shim coils with shim coils data acquisition operating parameters to shim said basic magnetic field;
a temperature sensor that senses a temperature directly on said gradient coils and that emits a temperature sensor signal representing said temperature;
a computer in communication with said sequence controller, said computer being supplied with said temperature sensor signal and said computer being configured to execute a field variable determining algorithm that determines a field variable, dependent on said temperature, that describes at least a portion of field drifts of said basic magnetic field that occur as a result of said temperature; and
said computer being configured to execute at least one field drift correction algorithm selected from the group consisting of modifying said gradient coils data acquisition parameters dependent on said field variable that causes said sequence controller to emit an electronic signal representing modified operating parameters for said gradient coils, a shim coils parameter modification algorithm that modifies said shim coils data acquisition parameters dependent on said field variable and that causes said sequence controller to emit an electrical signal to said shim coils representing modified operating parameters for said shim coils, and a post-processing algorithm that post-processes said magnetic resonance data acquired from said subject to correct, dependent on said field variable, effects of fields drifts that occur due to said temperature and that results in said computer emitting post-processed magnetic resonance data in electronic form as a data file.
